(19) United States
(12) Patent Application Publication
(10) Pub. No.: US 2009/0250787 A1
(43) Pub. Date: Oct. 8, 2009

(54) SEMICONDUCTOR STORAGE DEVICE AND MANUFACTURING METHOD OF THE SAME

(76) Inventor: Toshie Kutsunai, Hyogo (JP)

Correspondence Address: MCDERMOTT WILL & EMERY LLP, 600 13TH STREET, NW, WASHINGTON, DC, 20005-3096, US

(21) Appl. No.: 12/409,105

(22) Filed: Mar. 23, 2009

(30) Foreign Application Priority Data
Apr. 7, 2008 (JP) 2008-099420

(51) Int. Cl. H01L 29/92; H01L 21/02

(52) U.S. Cl. 257/532; 438/386; 257/301; 257/E29.343; 257/E21.008

(57) ABSTRACT

A semiconductor storage device includes: a first conductive adhesive layer selectively formed over a semiconductor substrate; an insulating film formed on the semiconductor substrate to cover the first conductive adhesive layer and having an opening exposing a central part of the first conductive adhesive layer; and a capacitive element including a bottom electrode formed along a bottom surface and a wall surface of the opening, a capacitive insulating film formed on the bottom electrode, and a top electrode formed on the capacitive insulating film. The first conductive adhesive layer is in contact with the bottom electrode only at a bottom surface part of the opening which includes a corner where the bottom surface of the opening meets the wall surface thereof.

### CROSS REFERENCE TO RELATED APPLICATIONS

This non-provisional application claims priority under 35 U.S.C. §119(a) on Patent Application No. 2008-099420 filed in Japan on Apr. 7, 2008, the entire contents of which are hereby incorporated by reference.

### TECHNICAL FIELD

The present disclosure relates to semiconductor storage devices and manufacturing methods thereof, and particularly relates to a semiconductor storage device, which is a ferroelectric memory device or a high dielectric constant memory device using a dielectric material, and a manufacturing method thereof.

### BACKGROUND ART

In development of ferroelectric memory devices, mass production of memory devices having small capacities of 1 kbit to 64 kbit and employing a planar structure have started first, and recently, memory devices in a stack structure having large capacities of 256 kbit to 4 Mbit are now developed dominantly. In the ferroelectric memory devices in a stack structure, contact plugs electrically connected to a semiconductor substrate are arranged immediately below bottom electrodes to reduce the cell size, thereby attaining high integration.

In future miniaturization, it is difficult for planar capacitive elements to secure the amount of charge necessary for memory operation. Accordingly, so-called three-dimensional stack structures of three-dimensional capacitive elements have been developed. In order to implement such a three-dimensional stack structure, a dielectric film and a top electrode with good coverage must be formed on a bottom electrode in a stepped form having an increased surface area.

Conventionally, the above structure has been achieved by forming a dielectric film and an electrode film within a concave hole by chemical vapor deposition (CVD) (see, Japanese Unexamined Patent Application Publication 2003-007859).

A structure of a dielectric capacitor in the above conventional dielectric memory device will now be described with reference to the drawing.

FIG. 14 shows a cross-section of the main part of a ferroelectric memory device in accordance with a conventional example. Above a semiconductor substrate 100, a storage contact hole is formed through a first interlayer insulating film 115 formed with an oxide 105 and a nitride (SiON) 110 as an anti-reflection film to be connected to an active region (not shown) of the semiconductor substrate 100. A polysilicon film 120 is formed in the lower part of the storage contact hole, and a barrier metals 125, 130 are formed on the polysilicon film 120 in the plug recess. The barrier metals 125, 130, are provided for preventing oxidation of polysilicon from being induced at the interface between the polysilicon plug and the storage electrode, which is caused by diffusing oxygen through the storage electrode in thermal treatment under high-temperature oxygen atmosphere.

In a storage node hole 155 as a capacitor in a concave shape formed in a second interlayer insulating film 150 on the barrier metal 130, a bottom electrode 160a, a first BST thin film 165, and a second BST thin film 170 are formed in this order. The bottom electrode 160a is formed by CVD and has a thickness of 5 nm to 50 nm. The first and second BST thin film 165, 170 are formed by ALD (atomic layer deposition), and CVD, respectively. Herein, the second BST thin film 170 is subjected to thermal treatment for crystallization under an oxygen atmosphere at a temperature of 650° C. to 800° C. Further, a top electrode 175 of platinum (Pt) is formed by CVD or sputtering to cover them.

By the above structure, a three-dimensional stacked capacitive element in a concave form is formed, thereby implementing a miniaturized and densely-integrated dielectric memory device.

### SUMMARY

However, in the above conventional example, a void may be formed in the bottom electrode 160 at the bottom of the storage node hole 155 in the thermal treatment for crystallizing the dielectric film, for example, the second BST thin film 170, thereby causing breakage. Such breakage of the bottom electrode 160a tends to be caused at the concave bottom where the step coverage is the worst.

Barium strontium titanate (BST) as a high dielectric constant material has a comparatively low crystallization temperature, 500° C. to 700° C. While, some ferroelectric films, of which a typical example is SBT (strontium bismuth tantalate), may have crystallization temperatures over 800° C. The higher the crystallization temperature is and the longer the treatment time is, the more remarkably the failure rate might increase.

Platinum (Pt) forming the top electrode 175, which is employed because of having excellent compatibility with the dielectric film, is excellent in ductility to tend to cause stress migration.

In view of the above, some combinations of a dielectric material and an electrode material may have high possibility of causing much breakage by thermal stress migration. Even selection of a combination having the lowest possibility thereof cannot prevent a single-bit failure in a memory device having a large capacity, unless the possibility of causing breakage is zero.

On the other hand, a technique for preventing breakage of the bottom electrode 160a has been known in which a conductive adhesive layer made of titanium oxide (TiOₓ), platinum oxide (PtOₓ), or the like is formed on the bottom and wall surfaces of the hole.

According to the knowledge that the inventors have acquired, when the conductive adhesive layer is provided between the bottom electrode and the interlayer insulating film and between the bottom electrode and the barrier metal so as to extend from the bottom to the wall of the concave hole in the conventional example, the following two problems arise.

The first problem is that formation of the conductive adhesive layer can still cause breakage of the bottom electrode. A result of evaluation by the inventors on this problem will be followed.

As shown in FIG. 15A, a first protection insulating film 3 is formed on a semiconductor substrate, in which transistors including source/drain regions 1 and a gate electrode 2 are integrated, to entirely cover the transistors. A contact plug 4 made of tungsten or polysilicon is formed in the first protection insulating film 3 to be connected to a source/drain region 1. An oxygen barrier film 5 is formed on the first protection insulating film 3 and is connected to the contact plug 4. The oxygen barrier film 5 is a stacked layer as a barrier layer against oxygen of TiAlN, Ir, and IrO₂ stacked in this order from below.

On the first protection insulating film 3, an interlayer insulating film 7 with a thickness of 300 nm to 800 nm having a planarized top surface is formed to electrically insulate adjacent oxygen barrier films 5 (only one layer is indicated in the figure), and to entirely cover the oxygen barrier films 5.

In the interlayer insulating film 7, a hole opening 6b for capacitive element formation is formed to expose the oxygen barrier film 5. In the hole opening 6b, a conductive adhesive layer 6 of PtOₓ with a thickness of 10 nm to 100 nm is formed to entirely cover the bottom and wall surfaces of the hole opening 6b. A bottom electrode 8 made of Pt is formed on the conductive adhesive layer 6. A capacitor film 9 made of SrBi₂(Ta₁₋ₓNbₓ)O₉ in a bismuth layered perovskite structure is formed on the bottom electrode 8. A top electrode 15 made of Pt is formed on the capacitor film 9. The film thicknesses of the bottom electrode 8, the capacitor film 9, and the top electrode 15 are 5 nm to 100 nm, 50 nm to 150 nm, and 50 nm to 100 nm, respectively.

FIG. 15B shows, in an enlarged scale, a contact corner 6a of the hole opening 6b immediately after deposition of a Pt film as the bottom electrode 8 in a three-dimensional stacked capacitive element in a the concave form shown in FIG. 15A. As shown in FIG. 15B, columnar crystals of the Pt film grow across each other from the conductive adhesive layer 6 as an underlying layer to collide at the bottom and wall surfaces of the contact corner 6a, thereby causing stress to form micro-voids.

Thereafter, as shown in FIG. 15C, the micro-voids aggregate in oxygen anneal at a temperature of 650° C. to 800° C. necessary for crystallization of the capacitor film 9 made of a high dielectric constant material or a ferroelectric material and formed on the bottom electrode 8, thereby forming a large void. Hence, the bottom electrode 8 may be broken at the contact corner 6a. This may remarkably decrease the remanent polarization (2Pr) of the capacitive element.

The void formation at the contact corner 6a also influences the tapered angle of the corner of the concave capacitor. The more obtuse the angle of the tapered wall, that is, the more larger the concave shape opens, the more the possibility of void formation decreases. However, a smaller angle is preferable for dense integration, and therefore, void formation cannot be avoided in practice.

The second problem is difficulty in using the PtOₓ conductive adhesive layer 6 itself. As shown in FIG. 16, in the case where the conductive adhesive layer 6 is formed below the entirety of the bottom electrode 8, namely, where the conductive adhesive layer 6 is formed over from the bottom surface to the wall surface of the hole opening 6b, the crystal grains receive influence of the underlying interlayer insulating film 7, for example, of silicon oxide to grow substantially uniformly in the transverse direction and the upward direction of the conductive adhesive layer 6. For this reason, it becomes difficult to uniformly grow the crystal grains at the contact corner 6a. This phenomenon can be observed in a conductive adhesive layer made of TiOₓ, as well. Such a phenomenon may prevent growth of the bottom electrode 8 (a Pt film) at the contact corner 6a, under which the conductive adhesive layer 6 is laid. This may increase the possibility of micro-void formation. As a result, the bottom electrode 8 may be broken to remarkably decrease the remanent polarization (2Pr) of the capacitive element.

The present invention has been made in view of the foregoing, and its objective is to prevent breakage of a bottom electrode by suppressing formation of micro-voids (a void) in the bottom electrode at a bottom corner of a hole in a three-dimensional stacked capacitive element in a concave shape.

To attain the above objective, a semiconductor storage device in accordance with the present invention has a structure in which, in forming a bottom electrode inside a concave opening formed in an insulating film, the size of crystal grains (grains) of the to-be-formed bottom electrode is made non-uniform between its bottom surface part and its wall surface part at a bottom corner of the opening where the bottom surface of the opening meets the wall surface thereof.

Specifically, a first semiconductor storage device in accordance with the present invention includes: a first conductive adhesive layer selectively formed over a semiconductor substrate; an insulating film formed on the semiconductor substrate to cover the first conductive adhesive layer and having an opening exposing a central part of the first conductive adhesive layer; and a capacitive element including a bottom electrode formed along a bottom surface and a wall surface of the opening, a capacitive insulating film formed on the bottom electrode, and a top electrode formed on the capacitive insulating film, wherein the first conductive adhesive layer is in contact with the bottom electrode only at a bottom surface part of the opening which includes a corner where the bottom surface of the opening meets the wall surface thereof.

According to the first semiconductor storage device, the size of the crystal grains of the bottom electrode is non-uniform between its bottom surface part and its wall surface part in the corner where the bottom surface of the opening meets the wall surface thereof. This suppresses formation of micro-voids in forming the bottom electrode on the bottom and wall surfaces of the opening, thereby preventing the bottom electrode from being broken.

A second semiconductor storage device in accordance with the present invention includes: a first conductive adhesive layer selectively formed over a semiconductor substrate; an insulating film formed on the semiconductor substrate to cover the first conductive adhesive layer and having an opening passing through a central part of the first conductive adhesive layer; and a capacitive element including a bottom electrode formed along a bottom surface and a wall surface of the opening, a capacitive insulating film formed on the bottom electrode, and a top electrode formed on the capacitive insulating film, wherein the first conductive adhesive layer is in contact with the bottom electrode only at a wall surface part of the opening which includes a corner where the bottom surface of the opening meets the wall surface thereof.

According to the second semiconductor storage device, the size of the crystal grains of the bottom electrode is non-uniform between its bottom surface part and its wall surface part in the corner where the bottom surface of the opening meets the wall surface thereof. This suppresses formation of micro-voids in forming the bottom electrode on the bottom and wall surfaces of the opening, thereby preventing the bottom electrode from being broken.

A third semiconductor storage device in accordance with the present invention, includes: a first conductive adhesive layer selectively formed over a semiconductor substrate; a second conductive adhesive layer formed on the first conductive adhesive layer; an insulating film formed on the semiconductor substrate to cover the first conductive adhesive layer and the second conductive adhesive layer, and having an opening passing through a central part of the second conductive adhesive layer and exposing the first conductive adhesive layer; and a capacitive element including a bottom electrode formed along a bottom surface and a wall surface of the opening, a capacitive insulating film formed on the bottom electrode, and a top electrode formed on the capacitive insulating film, wherein the first conductive adhesive layer is in contact with the bottom electrode only at a bottom surface part of the opening which includes a corner where the bottom surface of the opening meets the wall surface thereof, while the second conductive adhesive layer is in contact with the bottom electrode only at a wall surface part of the opening which includes the corner where the bottom surface of the opening meets the wall surface thereof, and the first conductive layer has crystal grains of which size is different from that of crystal grains of the second conductive adhesive layer.

According to the third semiconductor storage device, the size of the crystal grains of the bottom electrode is non-uniform between its bottom surface part and its wall surface part in the corner where the bottom surface of the opening meets the wall surface thereof. This suppresses formation of micro-voids in forming the bottom electrode on the bottom and wall surfaces of the opening, thereby preventing the bottom electrode from being broken.

In any of the first to third semiconductor storage devices, the first conductive adhesive layer may have a central opening.

In any of the first to third semiconductor storage devices, it is preferable that the opening is in a hole shape or a trench shape.

In any of the first to third semiconductor storage devices, a barrier layer is preferably formed below the first conductive adhesive layer to be in contact with the first adhesive layer.

In this case, the first conductive adhesive layer preferably contains the same element as the barrier film.

In any of the first to third semiconductor storage devices, the first conductive adhesive layer preferably contains the same element as the bottom electrode.

In any of the first to third semiconductor storage devices, it is preferable that the first conductive adhesive layer is made of at least one of platinum oxide, platinum iridium oxide, platinum palladium oxide, and platinum ruthenium oxide.

In the third semiconductor storage device, preferably, the second conductive adhesive layer contains the same element as the bottom electrode.

In the third semiconductor storage device, preferably, the second conductive adhesive layer is made of at least one of platinum oxide, platinum iridium oxide, platinum palladium oxide, and platinum ruthenium oxide.

In any of the first to third semiconductor storage devices, it is preferable that the bottom electrode contains platinum.

A first semiconductor storage device manufacturing method in accordance with the present invention includes: (a) selectively forming a first conductive adhesive layer over a semiconductor substrate; (b) forming an insulating film on the semiconductor substrate to cover the first conductive adhesive layer; (c) forming in the insulating film an opening exposing a central part of the first conductive adhesive layer by selectively etching the insulating film; (d) forming a first conductive film along a bottom surface and a wall surface of the opening; (e) forming an insulating metal oxide film on the first conductive film; (f) crystallizing the insulating metal oxide film by performing thermal treatment on the insulating metal oxide film; (g) forming a second conductive film on the insulating metal oxide film; and (h) performing patterning so as to leave the second insulating film, the insulating metal oxide film, and the first conductive film in the opening to form a top electrode from the second conductive layer, to form a capacitive insulating film from the insulating metal oxide film, and to form a bottom electrode from the first conductive film, thereby forming a capacitive element including the bottom electrode, the capacitive insulating film, and the top electrode, wherein in (c), the opening is formed so that the first conductive film in (d) is in contact with the first conductive adhesive layer only at a bottom surface part of the opening which includes a corner where the bottom surface of the opening meets the wall surface thereof.

According to the first semiconductor storage device manufacturing method, the size of the crystal grains of the bottom electrode is non-uniform between its bottom surface part and its wall surface part in the corner where the bottom surface of the opening meets the wall surface thereof. This suppresses formation of micro-voids in forming the bottom electrode on the bottom and wall surfaces of the opening, thereby preventing the bottom electrode from being broken.

A second semiconductor storage device manufacturing method in accordance with the present invention includes: (a) selectively forming a first conductive adhesive layer over a semiconductor substrate; (b) forming an insulating film on the semiconductor substrate to cover the first conductive adhesive layer; (c) forming in the insulating film an opening passing through a central part of the first conductive adhesive layer by selectively etching the insulating film and the first conductive adhesive layer; (d) forming a first conductive film along a bottom surface and a wall surface of the opening; (e) forming an insulating metal oxide film on the first conductive film; (f) crystallizing the insulating metal oxide film by performing thermal treatment on the insulating metal oxide film; (g) forming a second conductive film on the insulating metal oxide film; and (h) performing patterning so as to leave the second insulating film, the insulating metal oxide film, and the first conductive film in the opening to form a top electrode from the second conductive layer, to form a capacitive insulating film from the insulating metal oxide film, and to form a bottom electrode from the first conductive film, thereby forming a capacitive element including the bottom electrode, the capacitive insulating film, and the top electrode, wherein in (c), the opening is formed so that the first conductive film in (d) is in contact with the first conductive adhesive layer only at a wall surface part of the opening which includes a corner where the bottom surface of the opening meets the wall surface thereof.

According to the second semiconductor storage device manufacturing method, the size of the crystal grains of the bottom electrode is non-uniform between its bottom surface part and its wall surface part in the corner where the bottom surface of the opening meets the wall surface thereof. This suppresses formation of micro-voids in forming the bottom electrode on the bottom and wall surfaces of the opening, thereby preventing the bottom electrode from being broken.

In the first or second semiconductor storage device manufacturing method, preferably, the opening is formed in a hole shape or a trench shape in (c).

A third semiconductor storage device manufacturing method in accordance with the present invention includes: (a) selectively forming a first conductive adhesive layer over a semiconductor substrate; (b) performing first thermal treatment on the first conductive adhesive layer; (c) forming, after (b), a second conductive adhesive layer on the first conductive adhesive layer; (d) forming an insulating film on the semiconductor substrate to cover the first conductive adhesive layer and the second conductive adhesive layer; (e) forming in the insulating film an opening passing through a central part of the second conductive adhesive layer and exposing a central part of the first conductive adhesive layer by selectively etching the insulating film and the second conductive adhesive layer; (f) forming a first conductive film along a bottom surface and a wall surface of the opening; (g) forming an insulating metal oxide film on the first conductive film; (h) performing second thermal treatment on the insulating metal oxide film to crystallize the insulating metal oxide film; (i) forming a second conductive film on the insulating metal oxide film; and (j) performing patterning so as to leave the second insulating film, the insulating metal oxide film, and the first conductive film in the opening to form a top electrode from the second conductive layer, to form a capacitive insulating film from the insulating metal oxide film, and to form a bottom electrode from the first conductive film, thereby forming a capacitive element including the bottom electrode, the capacitive insulating film, and the top electrode, wherein in (e), the opening is formed so that the first conductive film in (f) is in contact with the first conductive adhesive layer only at a bottom surface part of the opening which includes a corner where the bottom surface of the opening meets the wall surface thereof, while being in contact with the second conductive adhesive layer only at a wall surface part of the opening which includes the corner where the bottom surface of the opening meets the wall surface thereof.

According to the third semiconductor storage device manufacturing method, the size of the crystal grains of the bottom electrode is non-uniform between its bottom surface part and its wall surface part in the corner where the bottom surface of the opening meets the wall surface thereof. This suppresses formation of micro-voids in forming the bottom electrode on the bottom and wall surfaces of the opening, thereby preventing the bottom electrode from being broken.

In the third semiconductor storage device manufacturing method, preferably, the opening is formed in a hole shape or a trench shape in (e).

The first or third semiconductor storage device manufacturing method may further includes (k) forming an opening in a central part of the first conductive adhesive layer between (a) and (c).

Any of the first to third semiconductor storage device manufacturing method may further includes (l) forming a barrier film on the semiconductor substrate before (a), wherein in (a), the first conductive adhesive layer is formed on the barrier film so as to be in contact with the barrier film.

In any of the first to third semiconductor storage device manufacturing method, preferably, the first conductive adhesive layer is formed by sputtering in (a).

In the third semiconductor storage device manufacturing method, preferably, the second conductive adhesive layer is formed by sputtering in (c).

Thus, according to the semiconductor storage devices and the manufacturing methods thereof in the present invention, in the three-dimensional stacked capacitive element in a concave shape, formation of micro-voids (a void), which tends to be caused in the bottom electrode at the bottom corner of the opening, can be suppressed to prevent the bottom electrode from being broken. Hence, a remarkable decrease in remanent polarization (2Pr) of the capacitive element can be prevented.

### BRIEF DESCRIPTION OF THE DRAWINGS

FIGS. 1A and 1B show the main part of a semiconductor storage device in accordance with Example Embodiment 1, in which FIG. 1A is a cross-sectional view taken along the line Ia-Ia in FIG. 1B, and FIG. 1B is as plan view.

FIGS. 2A to 2C are cross-sectional views sequentially showing steps of a semiconductor storage device manufacturing method in accordance with Example Embodiment 1.

FIGS. 3A and 3B are cross-sectional views sequentially showing steps of the semiconductor storage device manufacturing method in accordance with Example Embodiment 1.

FIG. 4 is a graph showing electric characteristics of a capacitive element of semiconductor storage devices in accordance with Example Embodiment 1 and that of a conventional example.

FIGS. SA and 5B show the main part of a semiconductor storage device in accordance with Example Embodiment 2, in which FIG. 5A is a cross-sectional view taken along the line Va-Va in FIG. 5B, and FIG. 5B is as plan view.

FIGS. 6A to 6C are cross-sectional views sequentially showing steps of a semiconductor storage device manufacturing method in accordance with Example Embodiment 2.

FIGS. 7A and 7B are cross-sectional views sequentially showing steps of the semiconductor storage device manufacturing method in accordance with Example Embodiment 2.

FIG. 8 is a cross-sectional view showing the main part of a semiconductor storage device in accordance with Example Embodiment 3.

FIGS. 9A to 9D are cross-sectional views sequentially showing steps of a semiconductor storage device manufacturing method in accordance with Example Embodiment 3.

FIGS. 10A to 10C are cross-sectional views sequentially showing steps of the semiconductor storage device manufacturing method in accordance with Example Embodiment 3.

FIGS. 11A and 11B are cross-sectional views sequentially showing steps of the semiconductor storage device manufacturing method in accordance with Example Embodiment 3.

FIG. 12 is a graph showing electric characteristics of capacitive elements of the semiconductor storage devices in accordance with Example Embodiments 1 to 3 and the conventional example.

FIG. 13 is a graph showing frequencies of occurrence of void formation in the capacitive elements of the semiconductor storage devices in accordance with the Example Embodiments 1 to 3 and the conventional example.

FIG. 14 is a cross-sectional view showing the main part of a conventional semiconductor storage device.

FIG. 15 is a cross-sectional view explaining a problem in the conventional semiconductor storage device.

FIG. 16 is a cross-sectional view explaining another problem in the conventional semiconductor storage device.

### BEST MODE FOR CARRYING OUT THE INVENTION

### Example Embodiment 1

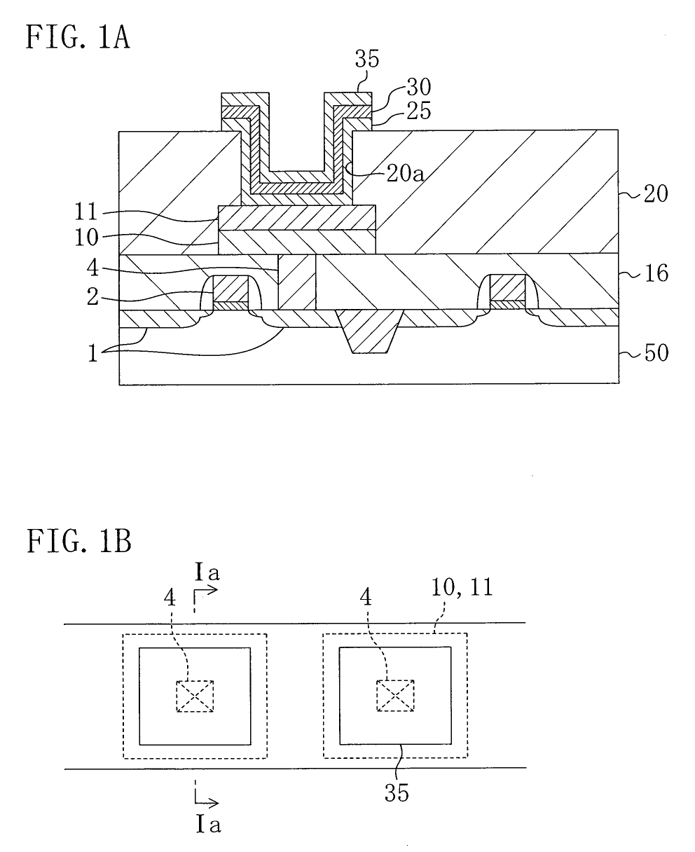

Example Embodiment 1 will be described below with reference to FIGS. 1 to 3.

FIGS. 1A and 1B show the main part of a semiconductor storage device in accordance with Example Embodiment 1, in which FIG. 1A is a cross-sectional view taken along the line Ia-Ia in FIG. 1B, and FIG. 1B is a plan view.

As shown in FIG. 1A, in the semiconductor storage device in accordance with the present exemplary embodiment, transistors including source/drain regions 1 and a gate electrode 2 are integrated in a semiconductor substrate 50, and a first interlayer insulating film 16 made of silicon oxide (SiO₂), for example, is formed on the semiconductor substrate 50 to entirely cover the transistors. A contact plug 4 made of tungsten or polysilicon and connected to a source/drain region 1 of a transistor is formed in the interlayer insulating film 16. On the interlayer insulating film 16, an oxygen barrier film 10 is formed to be connected to the contact plug 4. The oxygen barrier film 10 is formed of titanium aluminum nitride (TiAlN), iridium (Ir), and iridium dioxide (IrO₂) as barrier layers against oxygen stacked in this order from below. The thicknesses of the barrier layers of TiAlN, Ir, and IrO₂ are 40 nm to 100 nm, 50 nm to 100 nm, and 50 nm to 100 nm, respectively.

On the oxygen barrier film 10, a conductive adhesive layer 11 is formed which has a thickness of 10 nm to 100 nm and which is made of platinum oxide (PtOₓ, where 1≦x≦2). A second interlayer insulating film 20 of silicon oxide with a thickness of 300 nm to 800 nm is formed to electrically insulate adjacent stacked films (only one is indicated in FIG. 1), which are including the oxygen barrier film 10 and the conductive adhesive layer 11, and to entirely cover the stacked films. The surface of the second interlayer insulating film 20 is planarized at a level higher than the surface of the conductive adhesive layer 11.

In the second interlayer insulating film 20, a hole opening 20a as a concave in which a capacitive element is formed is formed to expose the conductive adhesive layer 11. Inside the hole opening 20a, a bottom electrode 25 of platinum is formed to entirely cover the bottom and wall surfaces of the hole opening 20a. A capacitor film 30 of strontium bismuth tantalate niobate (SrBi₂(Ta₁₋ₓNbₓ)O₉) in a bismuth layer perovskite structure is formed on the bottom electrode 25. A top electrode 35 of Pt is formed on the capacitor film 30. The film thicknesses of the bottom electrode 25, the capacitor film 30, and the top electrode 35 are 5 nm to 100 nm, 50 nm to 150 nm, and 50 nm to 100 nm, respectively. Herein, the top electrode 35, the capacitor film 30, and the bottom electrode 25 are etched and patterned using the same mask. In view of the adhesiveness between the underlying layers and the upper layers, residues in the processes, and the like, different masks may be used for the formation.

As shown in FIG. 1B, the top electrode 35 is arranged independently in each storage node in the transverse direction in the figure (the lengthwise direction in FIG. 1A), but may be formed over a plurality of storage nodes in common. The oxygen barrier film 10 is provided below the three-dimensional stacked capacitive element in the concave shape, specifically, between the contact plug 4 and the conductive adhesive layer 11. However, in the case using a dielectric film of a metal oxide having a comparatively low crystallization temperature, such as a metal oxide of PZT (lead zirconate titanate) base, BLT base, BST base, or the like, or in the case using, for example, a nitrogen atmosphere as the atmosphere for crystallization, the oxygen barrier film 10 may not necessarily be formed.

The conductive adhesive layer 11 provided in the capacitive element in a concave shape in accordance with the first exemplary embodiment is in contact with the bottom electrode 25 only at the bottom of the hole opening 20a. As long as the conductive adhesive layer 11 is in contact with at least a part of the bottom electrode 25, the bottom electrode 25 can hardly peel off from the second interlayer insulating film 20.

With reference to the drawings, a method for manufacturing the thus structured semiconductor storage device will be described next.

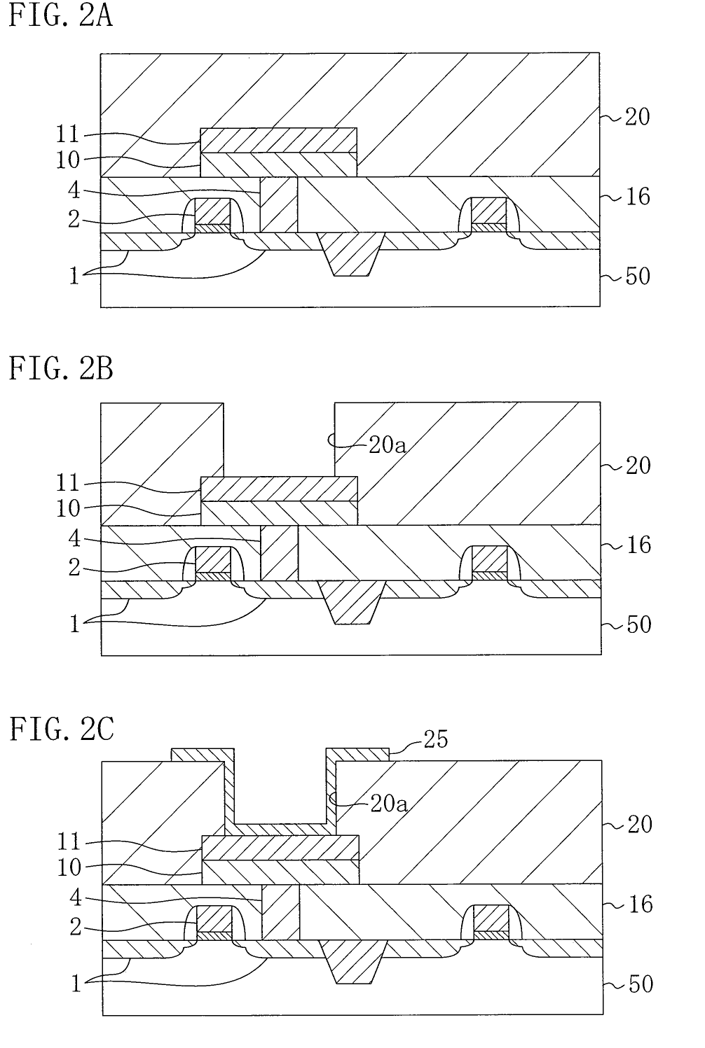

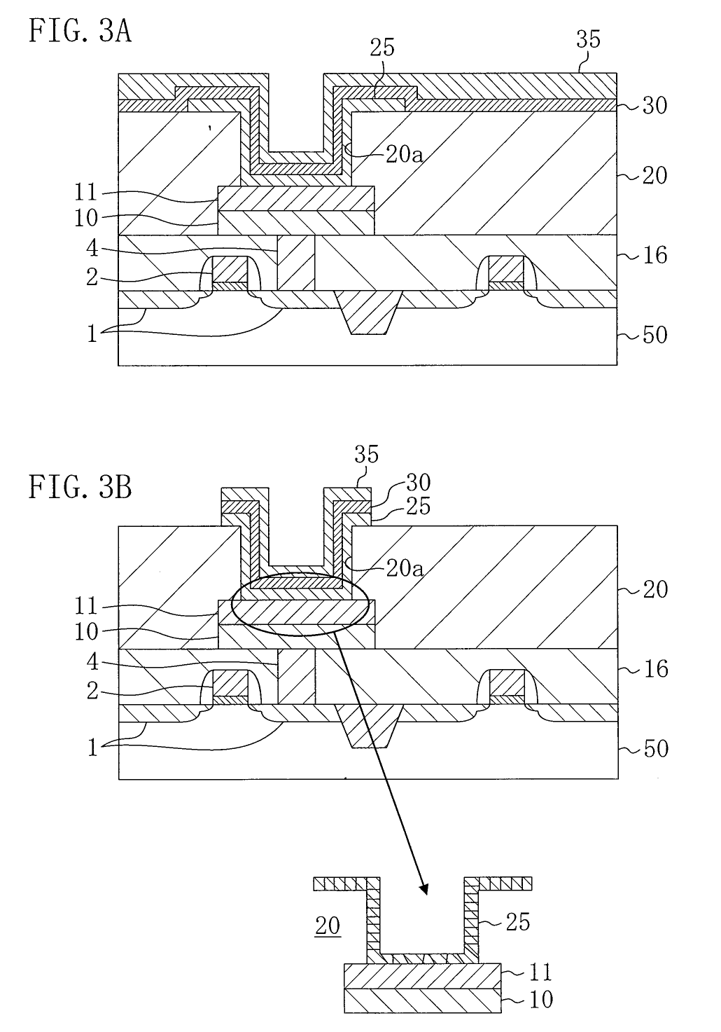

FIGS. 2A to 2C, 3A, and 3B are cross-sectional views sequentially showing steps of the semiconductor storage device manufacturing method in accordance with Example Embodiment 1.

First, as shown in FIG. 2A, the first interlayer insulating film 16 made of silicon oxide is formed to entirely cover the semiconductor 50 on which transistors including the source/drain regions 1 and the gate electrode 2 are integrated, and the top surface of the thus formed first interlayer insulating film 16 is planarized by chemical mechanical polishing (CMP) or the like. Then, dry etching is performed to form the contact hole connected to a source/drain region 1 of a transistor in the thus planarized first interlayer insulating film 16. By combination of CVD and etching back or CVD and CMP, the contact plug 4 of tungsten or polysilicon is formed inside the contact hole. Then, a TiAlN layer, an Ir layer, and an IrO₂ layer to form the oxygen barrier film 10 are formed in this order from below on the interlayer insulating film 16 including the contact plug 4 by sputtering. Sputtering is further performed to form the conductive adhesive layer 11 of PtOₓ on the oxygen barrier film 10. Then, dry etching is performed to pattern the stacked film of the oxygen barrier film 10 and the conductive adhesive layer 11 in a region including the contact plug 4. The second interlayer insulating film 20 of silicon oxide with a thickness of 300 nm to 800 nm is formed by CVD on the interlayer insulating film 16 to cover the conductive adhesive layer 11 and the oxygen barrier film 10. Then, the surface of the thus formed second interlayer insulating film 20 is planarized.

Next, as shown in FIG. 2B, dry etching using a mask (not shown) is performed to form the hole opening 20a in the second interlayer insulating film 20 to expose the central part of the conductive adhesive layer 11.

Subsequently, as shown in FIG. 2C, sputtering is performed to form a first conductive film to be a bottom electrode of Pt with a thickness of 5 nm to 50 nm on the entirety of the second interlayer insulating film 20 including the hole opening 20a. Then, the first conductive film is patterned using a mask (not shown) to electrically separate the storage node contact holes.

Thereafter, as shown in FIG. 3A, metal organic decomposition (MOD), metal organic chemical vapor deposition (MOCVD), or sputtering is performed to form the capacitor film 30 of SrBi₂(Ta₁₋ₓNbₓ)O₉ with a thickness of 50 nm to 150 nm as an insulating metal oxide in a bismuth layered perovskite structure on the second interlayer insulating film 20 and the first conductive film. Sputtering is further performed to form a second conductive film to be a top electrode of Pt with a thickness of 50 nm to 100 nm on the capacitor film 30. Then, thermal treatment is performed on the capacitor film 30 under an oxygen atmosphere at a temperature of 650° C. to 800° C. to crystallize the capacitor film 30.

Next, as shown in FIG. 3B, after a resist pattern (not shown) covering a part of the second conductive film which corresponds to the first conductive film is formed, dry etching using the thus formed resist pattern as a mask is performed to pattern the second conductive film, the capacitor film 30, and the first conductive film sequentially, thereby forming a capacitive element including the top electrode 35, the capacitor film 30, and the bottom electrode 25. Herein, the top electrode 30, the capacitor film 30, and the bottom electrode 25 are patterned using the same mask, but may be patterned using different masks.

The first conductive film may be patterned into the bottom electrode 25 having a predetermined final shape by the first patterning shown in FIG. 2C.

Hence, according to the semiconductor storage device and the manufacturing method thereof in Example Embodiment 1, the conductive adhesive layer 11 is formed between the bottom electrode 25 and the oxygen barrier film 10 therebelow, namely, only the lower side of the bottom electrode 25 in the bottom of the hole opening 20a, while not being formed between the bottom electrode 25 and the second interlayer insulating film 20 exposed from the wall of the hole opening 20a. Accordingly, the wall surface of the hole opening 20a at the corner where the bottom surface meets the wall surface is made of silicon oxide, while the bottom surface thereof is made of PtOₓ. This means that at the corner where the bottom surface of the hole opening 20a meets the wall surface thereof, the compositions of the adjacent underlying layers are different from each other. Difference in composition between the underlying layers of the bottom electrode 25 makes the size of the crystal grains at a part in contact with the conductive adhesive layer 11 and that at a part in contact with the second interlayer insulating film 20 non-uniform in forming the bottom electrode 25, as shown in an enlarged scale in FIG. 3B. For this reason, formation of micro-voids can be suppressed, which is caused due to stress by collision in the crystal growth directions of the material forming the bottom electrode 25 at the corner of the bottom electrode 25 where the bottom surface of the hole opening 20a meets the wall surface thereof. Hence, void formation can be prevented at the corner even when the capacitor film (ferroelectric film) 30 is subjected to high temperature thermal treatment at a temperature of 800° C. for crystallization thereof.

Description will be given now of a result of characteristic comparison between the semiconductor storage device in accordance with the comparative example and that in accordance with to Example Embodiment 1.

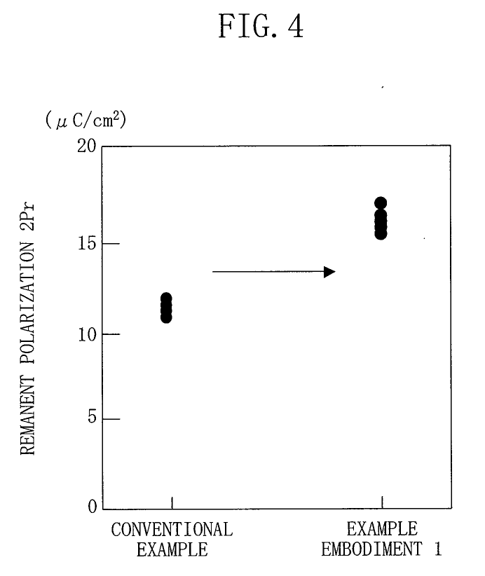

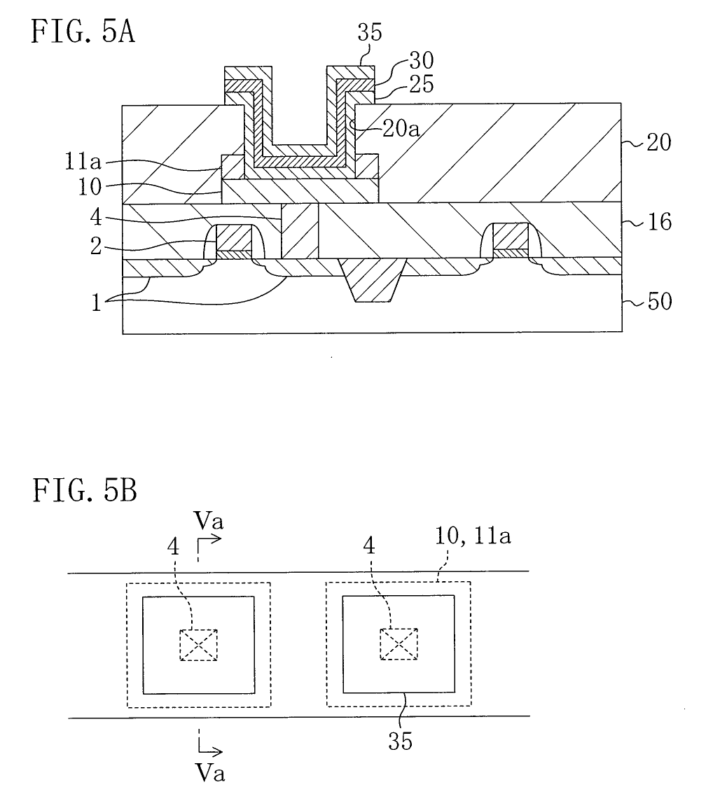

FIG. 4 shows results of evaluation on the remanent polarization (2Pr) of the capacitive element in accordance with the comparative example and that in accordance with Example Embodiment 1. In the conventional example, the remanent polarization (2Pr) shows comparatively small values of 11 μC/cm² to 12 μC/cm². This might be because, in the comparative example, a void is formed at the corner of the hole opening to break the bottom electrode in oxygen anneal at a high temperature necessary for crystallizing a high dielectric constant material or a ferroelectric material forming the capacitor film.

In contrast, in the present exemplary embodiment, the values of the remanent polarization (2Pr) on all points on the wafer surface are large, 15 μC/cm² to 17 μC/cm². This might because, as described above, suppression of void formation at the corner of the hole opening 20a results in no breakage of the bottom electrode 25 even through oxygen anneal is performed at a high temperature necessary for crystallizing the high dielectric constant material or the ferroelectric material forming the capacitor film 30.

### Example Embodiment 2

Example Embodiment 2 will be described below with reference to FIG. 5 to FIG. 7.

FIGS. 5A and 5B show the main part of a semiconductor storage device in accordance with Example Embodiment 2, in which FIG. 5A is a cross-sectional view taken along the line Va-Va in FIG. 5B, and FIG. 5B is a plan view. In FIG. 5, the same reference numerals are assigned to the same elements as those in FIG. 1 for omitting the description thereof.

Difference of the semiconductor storage device of Example Embodiment 2 from that of Example Embodiment 1 lies in that, as shown in FIG. 5A, a hole opening 20a formed in the second interlayer insulating film 20 passes through a conductive adhesive layer 11a and exposes the oxygen barrier film 10 therebelow. The hole opening 20a passing through the conductive adhesive layer 11a allows the conductive adhesive layer 11a to be in contact with the bottom electrode 25 at the wall surface of the hole opening 20a which includes the bottom corner thereof. Accordingly, the underlying layers of the bottom electrode 25 at the bottom surface of the hole opening 20a is different in composition from that at the wall surface thereof in forming the bottom electrode 25 inside the opening hole 20a.

Specifically, the conductive adhesive layer 11a provided for the concave capacitive element in Example Embodiment 2 is in contact with the bottom electrode 25 only at the lower part of the wall surface of the hole opening 20a. As long as the conductive adhesive layer 11a is in contact with at least a part of the bottom electrode 25, the bottom electrode 25 can hardly peel off from the second interlayer insulating film 20.

With reference to the drawings, a method for manufacturing the thus structured semiconductor storage device will be described next.

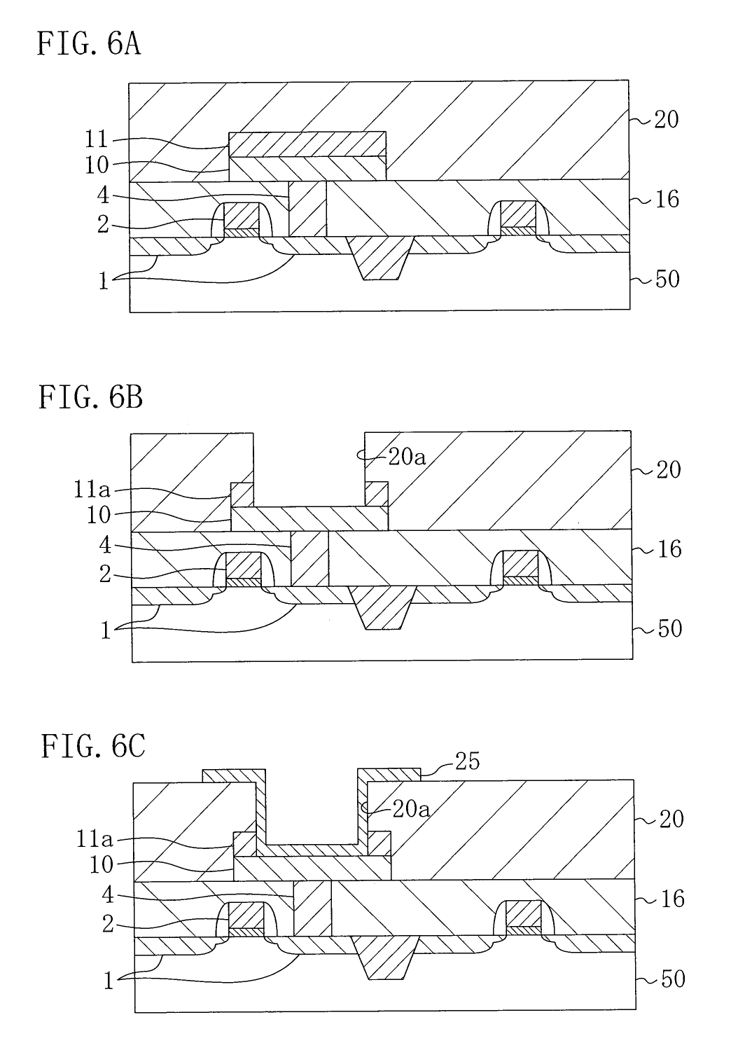

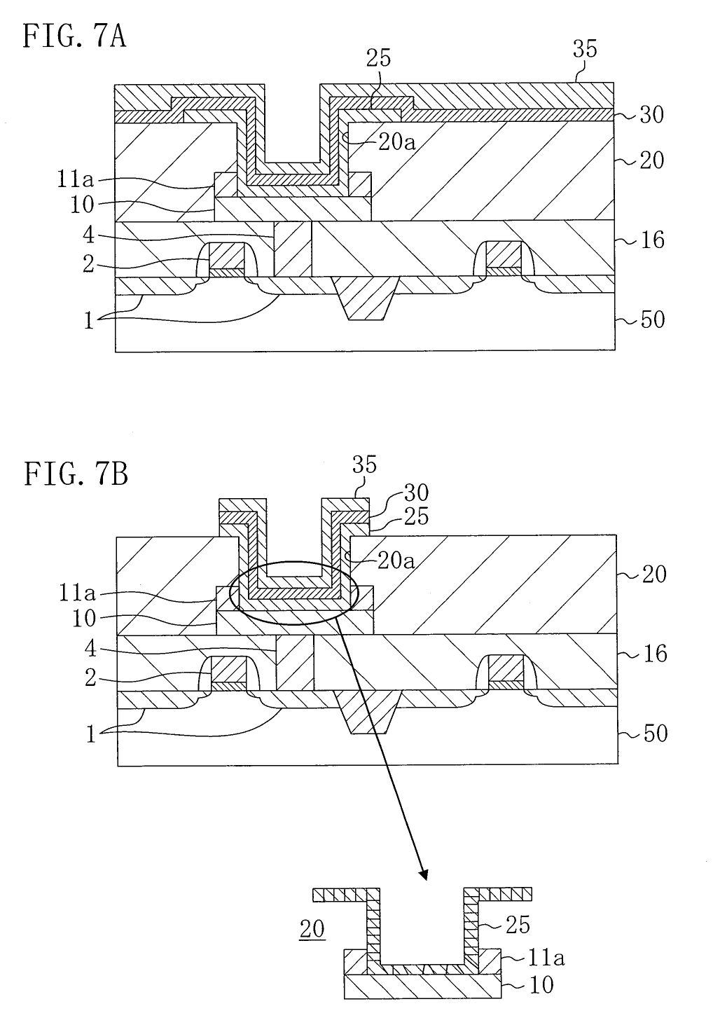

FIGS. 6A to 6C, 7A, and 7B are cross-sectional views sequentially showing steps of the semiconductor storage device manufacturing method in accordance with Example Embodiment 2.

As shown in FIG. 6A, the first interlayer insulating film 16 is formed to entirely cover the semiconductor 50 on which transistors including the source/drain regions 1 and the gate electrode 2 are integrated, and the top surface of the thus formed first interlayer insulating film 16 is planarized by chemical mechanical polishing (CMP) or the like. Then, dry etching is performed to form the contact hole connected to a source/drain region 1 of a transistor in the thus planarized first interlayer insulating film 16. By combination of CVD and etching back or CVD and CMP, the contact plug 4 of tungsten or polysilicon is formed inside the contact hole. Then, a TiAlN layer, an Ir layer, and an IrO₂ layer to form the oxygen barrier film 10 are formed in this order from below on the interlayer insulating film 16 including the contact plug 4 by sputtering. Sputtering is further performed to form the conductive adhesive layer 11 of PtOₓ on the oxygen barrier film 10. Then, dry etching is performed to pattern the stacked film of the oxygen barrier film 10 and the conductive adhesive layer 11 in a region including the contact plug 4. The second interlayer insulating film 20 of SiO₂ with a thickness of 300 nm to 800 nm is formed by CVD on the interlayer insulating film 16 to cover the conductive adhesive layer 11 and the oxygen barrier film 10. Then, the surface of the thus formed second interlayer insulating film 20 is planarized.

Next, as shown in FIG. 6B, dry etching using a mask (not shown) is performed to form the hole opening 20a in the second interlayer insulating film 20 which passes through the central part of the conductive adhesive layer 11 and which exposes the oxygen barrier film 10 therebelow. Thus, the conductive adhesive layer 11 is formed into the conductive adhesive layer 11a exposed at the open end surface at the lower part of the wall surface of the hole opening 20a.

Subsequently, as shown in FIG. 6C, sputtering is performed to form a first conductive film to be a bottom electrode made of Pt with a thickness of 5 nm to 50 nm on the entirety of the second interlayer insulating film 20 including the hole opening 20a. Herein, the first conductive film formed is in contact with the conductive adhesive layer 11a only at the lower part of the wall surface of the hole opening 20a which includes the bottom corner thereof. Then, the first conductive film is patterned using a mask (not shown) to electrically separate the storage node contact holes.

Thereafter, as shown in FIG. 7A, MOD, MOCVD, or sputtering is performed to form the capacitor film 30 of SrBi₂(Ta₁₋ₓNbₓ)O₉ in a bismuth layered perovskite structure with a thickness of 50 nm to 150 nm on the second interlayer insulating film 20 and the first conductive film. Sputtering is further performed to form a second conductive film to be a top electrode made of Pt with a thickness of 50 nm to 100 nm on the capacitor film 30. Then, thermal treatment is performed on the capacitor film 30 under an oxygen atmosphere at a temperature of 650° C. to 800° C. to crystallize the capacitor film 30.

Next, as shown in FIG. 7B, after a resist pattern (not shown) covering a part of the second conductive film which corresponds to the first conductive film is formed, dry etching using the thus formed resist pattern as a mask is performed to pattern the second conductive film, the capacitor film 30, and the first conductive film sequentially, thereby forming a capacitive element including the top electrode 35, the capacitor film 30, the bottom electrode 25. Herein, the top electrode 30, the capacitor film 30, and the bottom electrode 25 are patterned using the same mask, but may be patterned using different masks.

The first conductive film may be patterned into the bottom electrode 25 having a predetermined final shape by the first patterning shown in FIG. 6C.

Hence, according to the semiconductor storage device and the manufacturing method thereof in Example Embodiment 2, the conductive adhesive layer 11a is formed only at the lower part of the wall surface of the bottom electrode 25 which includes the corner where the bottom surface of the hole opening 20a meets the wall surface thereof, while not being formed at the bottom of the hole opening 20a. Accordingly, the lower part of the wall surface of the hole opening 20a which includes the corner where the bottom surface of the hole opening 20a meets the wall surface thereof is made of PtOₓ, while the bottom surface thereof is made of IrO₂ as the uppermost layer of the barrier film 10. This means that the compositions of the adjacent underlying layers are different from each other at the corner of the hole opening 20a. Difference in composition between the underlying layers of the bottom electrode 25 makes the size of the crystal grains at a part in contact with the conductive adhesive layer 11a and that at a part in contact with the barrier film 10 non-uniform in forming the bottom electrode 25, as shown in an enlarged scale in FIG. 7B. For this reason, formation of micro-voids can be suppressed which is caused due to stress by collision in the crystal growth directions of the material forming the bottom electrode 25 at the corner of the bottom electrode 25 where the bottom surface of the hole opening 20a meets the wall surface thereof. Hence, void formation can be prevented at the corner even when the capacitor film (ferroelectric film) 30 is subjected to thermal treatment at a high temperature of 800° C. for crystallization thereof.

### Example Embodiment 3

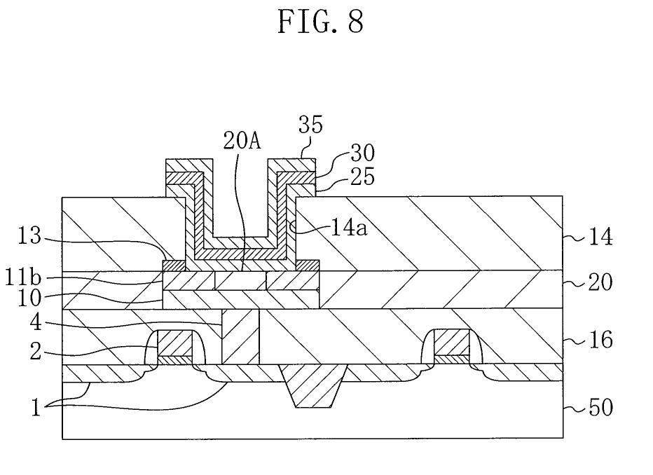

Example Embodiment 3 will be described below with reference to FIG. 8 to FIG. 11.

FIG. 8 shows the section of the main part of a semiconductor storage device in accordance with Example Embodiment 2. In FIG. 8, the same reference numerals are assigned to the same elements as those in FIG. 1 for omitting the description thereof.

Difference of the semiconductor storage device of Example Embodiment 3 from that of Example Embodiment 2 lies in that, as shown in FIG. 8, a conductive adhesive layer is formed with a stacked film of a first conductive adhesive layer 11b and a second conductive adhesive layer 13 thereon, and the second conductive adhesive layer 13 is opened at its central part to expose the first conductive adhesive layer 11b. Accordingly, the bottom electrode 25 is in contact with the first conductive adhesive layer 11b at the bottom corner of the hole opening 14a, while being in contact with the second conductive adhesive layer 13 at the lower part of the wall surface of the hole opening 14a which includes the bottom corner.

Herein, both the first conductive adhesive layer 11b and the second conductive adhesive layer 13 have a film thickness of 10 nm to 100 nm, and are made of PtOₓ. Further, the first conductive adhesive layer 11b is subjected to thermal treatment under a nitrogen atmosphere for densification. Accordingly, the first conductive adhesive layer 11b and the second conductive adhesive layer 13 as underlying layers of the bottom electrode 25 at the bottom surface and the wall surface of the hole opening 14a are different from each other in size of the crystal grains.

A part of the first conductive adhesive layer 11b which is more inside than the removed part of the second conductive adhesive layer 13 is removed to form an opening exposing the oxygen barrier film 10 therebelow. In this opening, a buried insulating film 20A is formed by burying the opening with the second interlayer insulating film 20. Herein, the opening of the first conductive adhesive layer 11b is formed by etching only the first conductive adhesive layer 11b so as not to pass through the oxygen barrier film 10.

In Example Embodiment 3, the second interlayer insulating film 20 is planarized together with the first conductive adhesive layer 11b and the buried insulating film 20A, and a third interlayer insulating film 14 made of silicon oxide is formed to cover the planarized second interlayer insulating film 20 and the second conductive adhesive layer 13 formed on the peripheral part of the first conductive adhesive layer 11b. Accordingly, the hole opening 14a exposing the first conductive adhesive layer 11b and the buried insulating film 20A is formed as a capacitive element formation hole for each storage node in the third interlayer insulating film 14.

The conductive adhesive layer 11b and the second conductive adhesive layer 13 provided in the concave capacitive element in Example Embodiment 3 are in contact with the bottom electrode 25 at only the peripheral part of the bottom surface and the lower part of the wall surface of the hole opening 14a, respectively. As long as the first conductive adhesive layer 11b and the second conductive adhesive layer 13 are in contact with at least part of the bottom electrode 25, the bottom electrode 25 can hardly peel off from the buried insulating film 20A and the third interlayer insulating film 14.

With reference to the drawings, a method for manufacturing the thus structured semiconductor storage device will be described next.

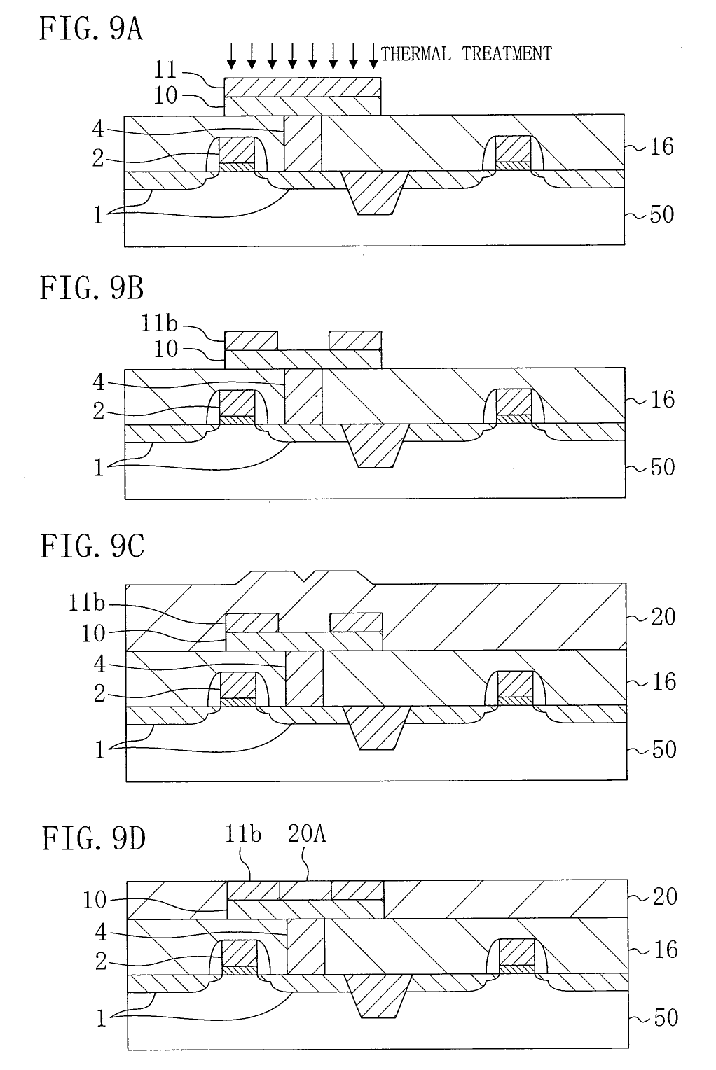

FIGS. 9A to 9D, 10A to 10C, 11A, and 11B cross-sectional views sequentially showing steps of the semiconductor storage device manufacturing method in accordance with Example Embodiment 3.

As shown in FIG. 9A, the first interlayer insulating film 16 is formed to entirely cover the semiconductor 50 on which transistors including the source/drain regions 1 and the gate electrode 2 are integrated, and the top surface of the thus formed first interlayer insulating film 16 is planarized by chemical mechanical polishing (CMP) or the like. Then, dry etching is performed to form the contact hole connected to a source/drain region 1 of a transistor in the thus planarized first interlayer insulating film 16. By combination of CVD and etching back or CVD and CMP, the contact plug 4 of tungsten or polysilicon is formed inside the contact hole. Then, a TiAlN layer, an Ir layer, and an IrO₂ layer to form the oxygen barrier film 10 are formed in this order from below on the interlayer insulating film 16 including the contact plug 4 by sputtering. Sputtering is further performed to form the first conductive adhesive layer 11 of PtOₓ on the oxygen barrier film 10. Then, thermal treatment under nitrogen atmosphere at a temperature of 450° C. to 600° C. is performed for densifying the thus formed first conductive adhesive layer 11. By this thermal treatment, the size of the crystal grains of the conductive adhesive layer 11 becomes larger than that before the thermal treatment. Thereafter, dry etching is performed to pattern the stacked layer of the oxygen barrier film 10 and the first conductive adhesive layer 11 in a region including the contact plug 4. The thermal treatment on the first conductive adhesive layer 11 may be performed after patterning.

Next, as shown in FIG. 9B, the central part of the conductive adhesive layer 11 is dry etched selectively to form, from the first conductive adhesive layer 11, the first conductive adhesive layer 11b having an opening exposing the oxygen barrier film 10.

Subsequently, as shown in FIG. 9C, the second interlayer insulating film 20 of SiO₂ with a thickness of 300 nm to 800 nm is formed on the interlayer insulating film 16 by CVD to cover the first conductive adhesive layer 11b and the oxygen barrier film 10.

Thereafter, as shown in FIG. 9D, the surface of the second interlayer insulating film 20 is planarized by CMP to expose the upper surface of the first conductive adhesive layer 11b, and to form the buried insulating film 20A in the opening of the first conductive adhesive layer 11b.

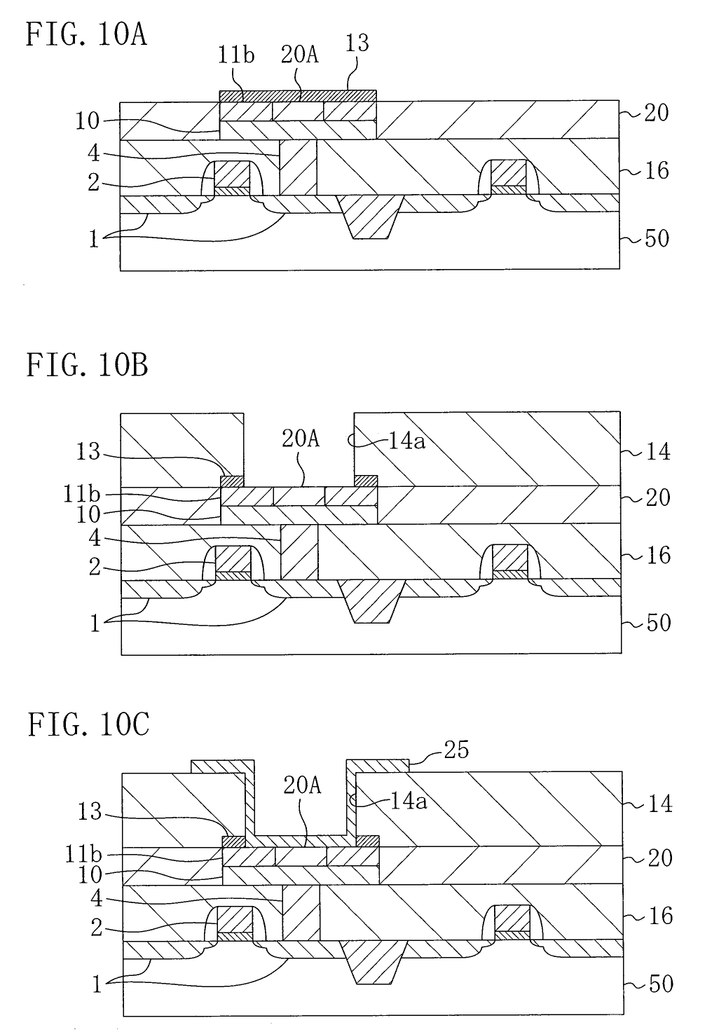

Next, as shown in FIG. 10A, a PtOₓ film is formed by sputtering on the second interlayer insulating film 20, the first conductive adhesive layer 11b, and the buried insulating film 20A. Then, the PtOₓ film is patterned by dry etching to form the second conductive adhesive layer 13 of PtOₓ on the first conductive adhesive layer 11b and the buried interlayer insulating film 20A.

Subsequently, as shown in FIG. 10B, a third interlayer insulating film 14 of SiO₂ with a thickness of 300 nm to 800 nm is formed on the second interlayer insulating film 20 by CVD to cover the second conductive adhesive layer 13, and then, the surface of the thus formed third interlayer insulating film 14 is planarized. The hole opening 14a is then formed in the third interlayer insulating film 14 by dry etching using a mask (not shown) to pass through the central part of the second conductive adhesive layer 13 and to expose the first conductive adhesive layer 11b and the buried insulating film 20A therebelow. Whereby, the open end surface of the second conductive adhesive layer 13 is exposed at the lower part of the wall surface of the hole opening 14a. The first conductive adhesive layer 11b is exposed at the peripheral part of the bottom surface of the hole opening 14a.

Thereafter, as shown in FIG. 10C, the first conductive film to be a bottom electrode of Pt with a thickness of 5 nm to 50 nm is formed on the entirety of the third interlayer insulating film 14 including the hole opening 14a. At this time point, the first conductive film formed is in contact with the second conductive adhesive layer 13 at the lower part of the wall surface of the hole opening 20a which includes its bottom corner, while being in contact with the first conductive adhesive layer 11b at only the bottom corner of the hole opening 20a. Then, the first conductive film is patterned using a mask (not shown) to electrically separate at least storage node contact holes. Thus, the bottom electrode 25 is formed which reaches the top surface of the third interlayer insulating film 14 along the bottom surface and the wall surface of the hole opening 14a.

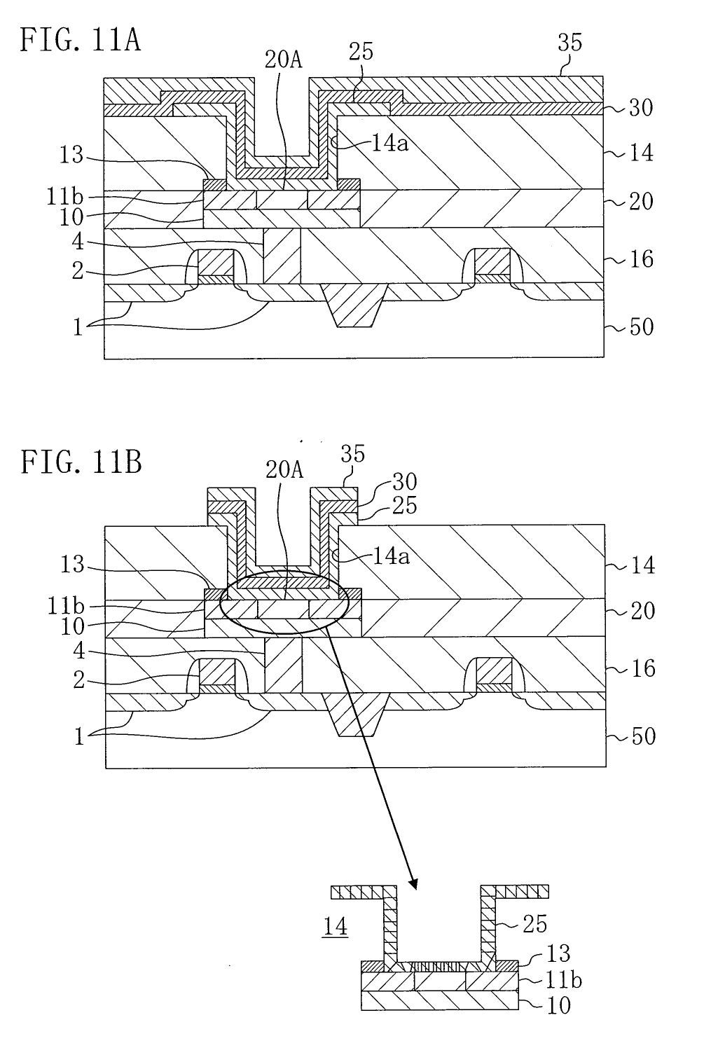

Thereafter, as shown in FIG. 11A, MOD, MOCVD, or sputtering is performed to form the capacitor film 30 of SrBi₂(Ta₁₋ₓNbₓ)O₉ in a bismuth layered perovskite structure with a thickness of 50 nm to 150 nm on the third interlayer insulating film 14 and the first conductive film. Sputtering is further performed to form a second conductive film to be a top electrode made of Pt with a thickness of 50 nm to 100 nm on the capacitor film 30. Then, thermal treatment is performed on the capacitor film 30 under an oxygen atmosphere at a temperature of 650° C. to 800° C. to crystallize the capacitor film 30.

Next, as shown in FIG. 11B, after a resist pattern (not shown) covering a part of the second conductive film which corresponds to the first conductive film is formed, dry etching using the thus formed resist pattern as a mask is performed to pattern the second conductive film, the capacitor film 30, and the first conductive film sequentially, thereby forming a capacitive element including the top electrode 35, the capacitor film 30, the bottom electrode 25. Herein, the top electrode 30, the capacitor film 30, and the bottom electrode 25 are patterned using the same mask, but may be patterned using different masks.

The first conductive film may be patterned into the bottom electrode 25 having a predetermined final shape by the first patterning shown in FIG. 10C.

In Example Embodiment 3, the central part of the conductive adhesive layer 11b is removed to form an opening. Because, the advantages of the present embodiment can be enjoyed when the crystal structures (grain sizes) are different between the underlying layers (the first conductive adhesive layer 11b and the second conductive adhesive layer 13 herein) from each other at at least the bottom corner of the hole opening 14a. In other words, because the central hole from which the first conductive adhesive layer 11b is removed can be buried with any material having a composition different from that of the first conductive adhesive layer 11b. The same can be applied to Example Embodiment 1. No problem is involved, of course, even if the central part of the first conductive adhesive layer 11b is not be removed and remains as it is.

Hence, in the semiconductor storage device and the manufacturing method thereof in accordance with Example Embodiment 3, the second conductive adhesive layer 13 is formed at the lower part of the wall surface of the opening hole 14a which includes the bottom corner where the bottom surface of the hole opening 14a meets the wall surface thereof, while the first conductive adhesive layer 11a, the size of the crystal grains of which is different from that of the second conductive adhesive layer 13, is formed at the peripheral part of the bottom surface of the hole opening 14a. Difference in composition between the underlying layers of the bottom electrode 25 makes the size of the crystal grains of the bottom electrode 25 non-uniform between the part in contact with the second conductive adhesive layer 13 and the part in contact with the first conductive adhesive layer 11b in forming the bottom electrode 25, as shown in an enlarged scale in FIG. 11B. Accordingly, formation of micro-voids can be suppressed, which is caused due to stress by collision in the crystal growth directions of the material of the bottom electrode 25 at the corner of the bottom electrode 25 where the bottom surface of the hole opening 14a meets the wall surface thereof. This can suppress formation of a void at the corner even when the capacitor film (ferroelectric film) 30 is subjected to thermal treatment at a high temperature of 800° C. for crystallization thereof.

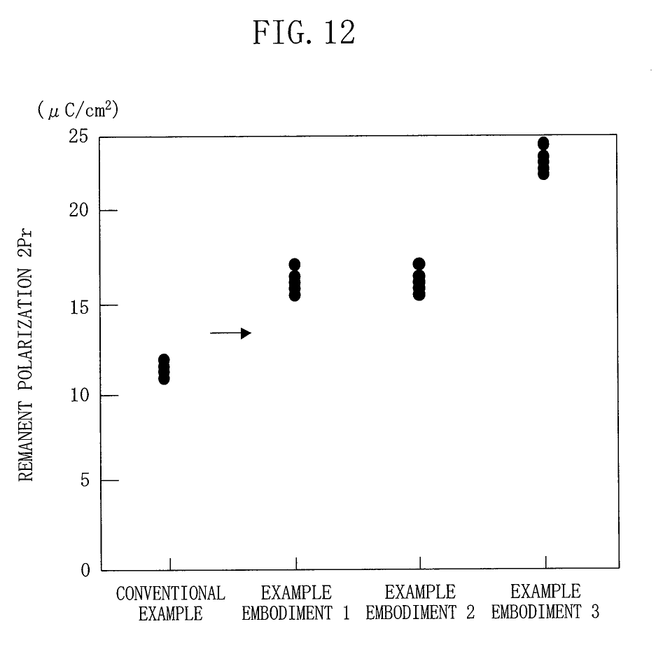

Results of evaluation on the remanent polarization (2Pr) of the capacitive elements in the semiconductor storage devices according to the conventional example and the present exemplary embodiments will be discussed next with reference to FIG. 12. As shown in FIG. 12, the conventional example has values of remanent polarization (2Pr) of 11 μC/cm² to 12 μC/cm². This might be because, as described above, void formation at the bottom corner of the hole opening is caused to cause the bottom electrode to be broken in high temperature oxygen anneal necessary for crystallization of a high dielectric constant material or a ferroelectric material.

On the other hand, referring to the present exemplary embodiments, the values of the remanent polarization (2Pr) at all points on the waver surface in Example Embodiments 1, 2, and 3 are less dispersed, namely, 15 μC/cm² to 17 μC/cm², 15 μC/cm² to 17 μC/cm², and 22 μC/cm² to 25 μC/cm², respectively, and hence, good remanent polarizations (2Pr) can be attained.

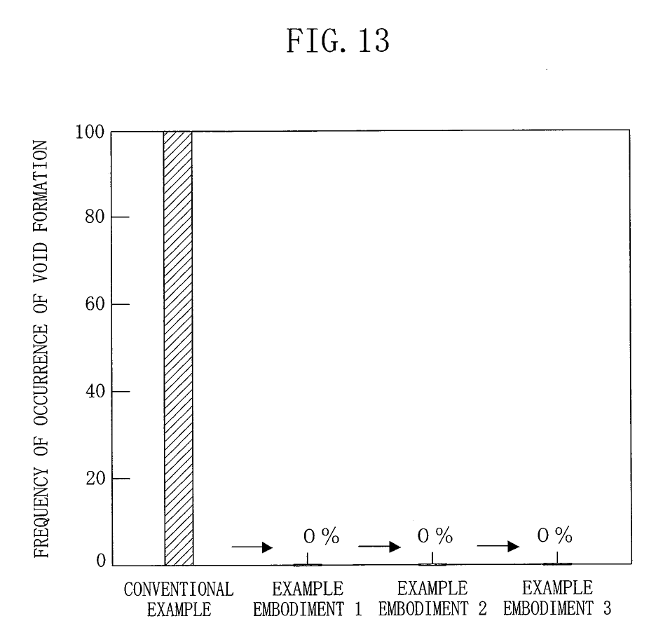

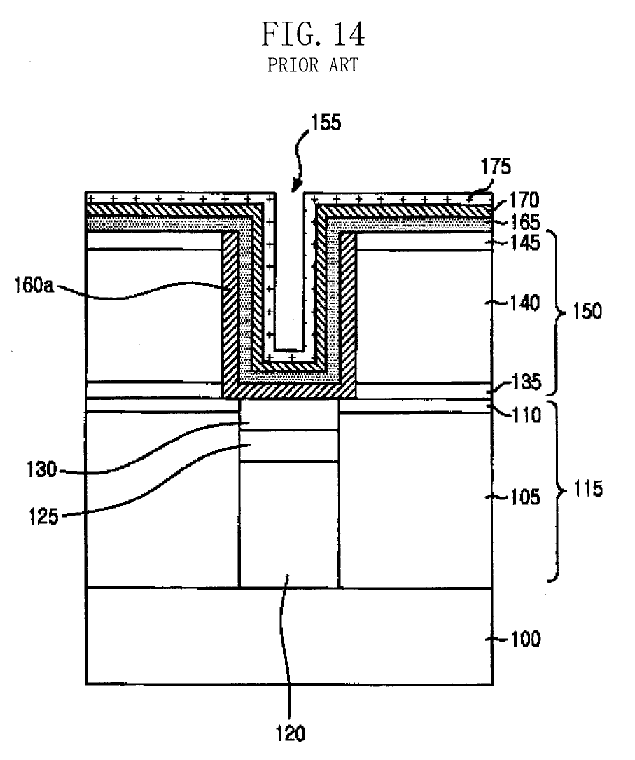

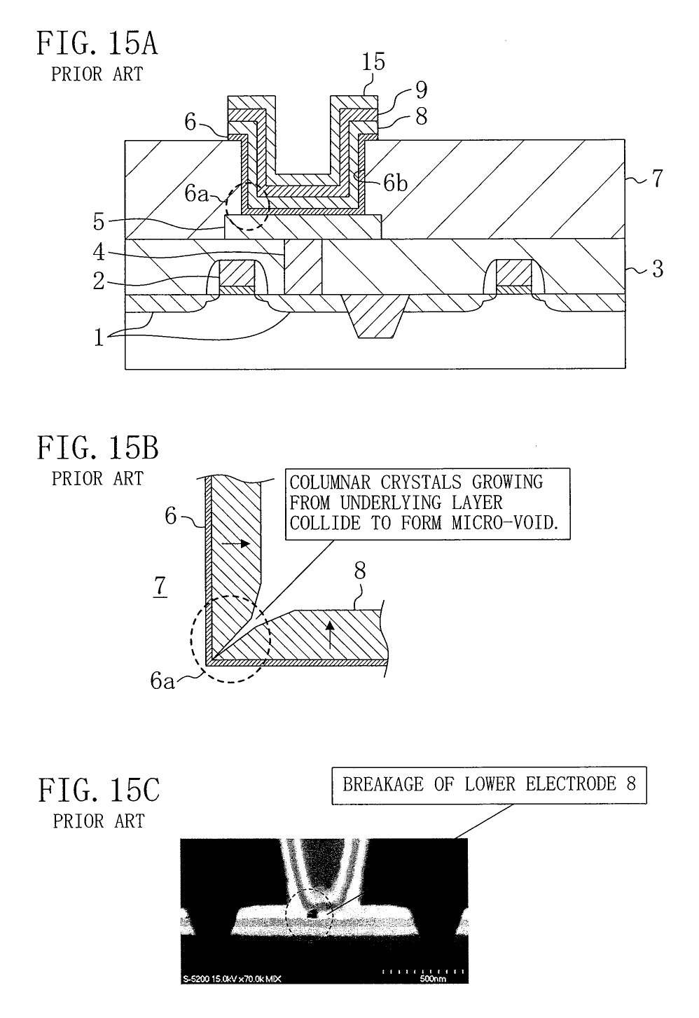

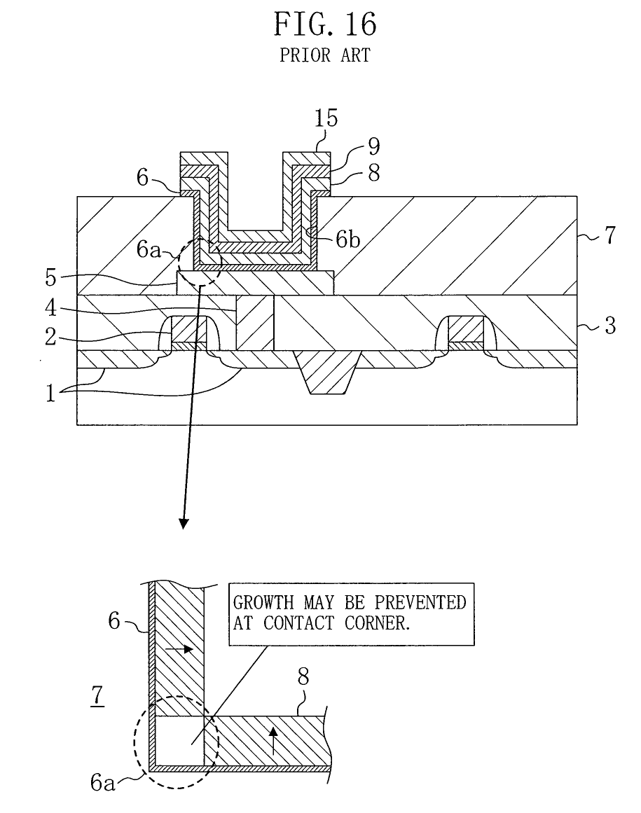

Next discussed with reference to FIG. 13 is results of evaluation on void formation at the bottom corner of the hole opening of the capacitive element in a concave shape of the semiconductor storage device in accordance with the present exemplary embodiment.

FIG. 13 depicts the results of evaluation on void formation at the bottom corner of the hole opening before and after thermal treatment at 800° C. at which the ferroelectric material is crystallized. As shown in FIG. 13, no void is formed at the corner of the capacitive element in the semiconductor storage device in accordance with the present exemplary embodiments even after thermal treatment at 800° C., which clearly proves that the present invention can remarkably improve the characteristics of a semiconductor storage device.

In Example Embodiments 1 to 3, platinum oxide (PtOₓ) is used as a material of the conductive adhesive layers 11, 11a, 11b, 13. However, any conductive material may be used which includes at least one of platinum oxide, platinum iridium oxide (PtIrOₓ), platinum palladium oxide (PtPdOₓ), and platinum ruthenium oxide (PtRuOₓ).

The bottom electrode 25 and the top electrode 35 are made of platinum (Pt), but may be iridium, ruthenium, or palladium, instead.

In Example Embodiment 3, the first conductive adhesive layer 11b and the second conductive adhesive layer 13 are the same in composition, while being made different in grain size from each other by whether the thermal treatment is performed. Instead, the grain size may be made different by changing the compositions thereof.

The hole opening 14a or 20a in Example Embodiments 1 to 3 has, but is not limited to, a shape of a contact hole. The hole opening may be in a trench shape in which the opening region extends in one direction, for example.

As described above, the semiconductor storage devices and the manufacturing methods thereof in accordance with the present exemplary embodiments can prevent the remanent polarization (2Pr) of the capacitive elements from decreasing by preventing breakage of the bottom electrode, and therefore are useful in high dielectric constant memory devices and ferroelectric memory devices in a three-dimensional stack structure using a dielectric material.

What is claimed is:

1. A semiconductor storage device, comprising:
a first conductive adhesive layer selectively formed over a semiconductor substrate;
an insulating film formed on the semiconductor substrate to cover the first conductive adhesive layer and having an opening exposing a central part of the first conductive adhesive layer; and
a capacitive element including a bottom electrode formed along a bottom surface and a wall surface of the opening, a capacitive insulating film formed on the bottom electrode, and a top electrode formed on the capacitive insulating film,
wherein the first conductive adhesive layer is in contact with the bottom electrode only at a bottom surface part of the opening which includes a corner where the bottom surface of the opening meets the wall surface thereof.

2. The semiconductor storage device of claim 1, wherein
the first conductive adhesive layer has a central opening.

3. The semiconductor storage device of claim 1, wherein
the opening is in a hole shape or a trench shape.

4. The semiconductor storage device of claim 1, further comprising:
a barrier layer formed below the first conductive adhesive layer to be in contact with the first adhesive layer.

5. The semiconductor storage device of claim 4, wherein
the first conductive adhesive layer contains the same element as the barrier film.

6. The semiconductor storage device of claim 1, wherein
the first conductive adhesive layer contains the same element as the bottom electrode.

7. The semiconductor storage device of claim 1, wherein
the first conductive adhesive layer is made of at least one of platinum oxide, platinum iridium oxide, platinum palladium oxide, and platinum ruthenium oxide.

8. The semiconductor storage device of claim 1, wherein
the bottom electrode contains platinum.

9. A semiconductor storage device, comprising:
a first conductive adhesive layer selectively formed over a semiconductor substrate;
an insulating film formed on the semiconductor substrate to cover the first conductive adhesive layer and having an opening passing through a central part of the first conductive adhesive layer; and
a capacitive element including a bottom electrode formed along a bottom surface and a wall surface of the opening, a capacitive insulating film formed on the bottom electrode, and a top electrode formed on the capacitive insulating film,
wherein the first conductive adhesive layer is in contact with the bottom electrode only at a wall surface part of the opening which includes a corner where the bottom surface of the opening meets the wall surface thereof.

10. The semiconductor storage device of claim 9, wherein
the opening is in a hole shape or a trench shape.

11. The semiconductor storage device of claim 9, further comprising:
a barrier layer formed below the first conductive adhesive layer to be in contact with the first adhesive layer.

12. The semiconductor storage device of claim 11, wherein
the first conductive adhesive layer contains the same element as the barrier film.

13. The semiconductor storage device of claim 9, wherein
the first conductive adhesive layer contains the same element as the bottom electrode.

14. The semiconductor storage device of claim 9, wherein
the first conductive adhesive layer is made of at least one of platinum oxide, platinum iridium oxide, platinum palladium oxide, and platinum ruthenium oxide.

15. The semiconductor storage device of claim 9, wherein
the bottom electrode contains platinum.

16. A semiconductor storage device, comprising:
a first conductive adhesive layer selectively formed over a semiconductor substrate;
a second conductive adhesive layer formed on the first conductive adhesive layer;
an insulating film formed on the semiconductor substrate to cover the first conductive adhesive layer and the second conductive adhesive layer, and having an opening passing through a central part of the second conductive adhesive layer and exposing the first conductive adhesive layer; and
a capacitive element including a bottom electrode formed along a bottom surface and a wall surface of the opening, a capacitive insulating film formed on the bottom electrode, and a top electrode formed on the capacitive insulating film,
wherein the first conductive adhesive layer is in contact with the bottom electrode only at a bottom surface part of the opening which includes a corner where the bottom surface of the opening meets the wall surface thereof, while the second conductive adhesive layer is in contact with the bottom electrode only at a wall surface part of the opening which includes the corner where the bottom surface of the opening meets the wall surface thereof, and
the first conductive layer has crystal grains of which size is different from that of crystal grains of the second conductive adhesive layer.

17. The semiconductor storage device of claim 16, wherein
the first conductive adhesive layer has a central opening.

18. The semiconductor storage device of claim 16, wherein
the opening is in a hole shape or a trench shape.

19. The semiconductor storage device of claim 16, further comprising:
a barrier layer formed below the first conductive adhesive layer to be in contact with the first adhesive layer.

20. The semiconductor storage device of claim 19, wherein
the first conductive adhesive layer contains the same element as the barrier film.

21. The semiconductor storage device of claim 16, wherein
the first conductive adhesive layer contains the same element as the bottom electrode.

22. The semiconductor storage device of claim 16, wherein
the first conductive adhesive layer is made of at least one of platinum oxide, platinum iridium oxide, platinum palladium oxide, and platinum ruthenium oxide.

23. The semiconductor storage device of claim 16, wherein
the second conductive adhesive layer contains the same element as the bottom electrode.

24. The semiconductor storage device of claim 16, wherein
the second conductive adhesive layer is made of at least one of platinum oxide, platinum iridium oxide, platinum palladium oxide, and platinum ruthenium oxide.

25. The semiconductor storage device of claim 16, wherein
the bottom electrode contains platinum.

26. A semiconductor storage device manufacturing method, comprising:
(a) selectively forming a first conductive adhesive layer over a semiconductor substrate;
(b) forming an insulating film on the semiconductor substrate to cover the first conductive adhesive layer;
(c) forming in the insulating film an opening exposing a central part of the first conductive adhesive layer by selectively etching the insulating film;
(d) forming a first conductive film along a bottom surface and a wall surface of the opening;
(e) forming an insulating metal oxide film on the first conductive film;
(f) crystallizing the insulating metal oxide film by performing thermal treatment on the insulating metal oxide film;
(g) forming a second conductive film on the insulating metal oxide film; and
(h) performing patterning so as to leave the second conductive film, the insulating metal oxide film, and the first conductive film in the opening to form a top electrode from the second conductive layer, to form a capacitive insulating film from the insulating metal oxide film, and to form a bottom electrode from the first conductive film, thereby forming a capacitive element including the bottom electrode, the capacitive insulating film, and the top electrode,
wherein in (c), the opening is formed so that the first conductive film in (d) is in contact with the first conductive adhesive layer only at a bottom surface part of the opening which includes a corner where the bottom surface of the opening meets the wall surface thereof.

27. The method of claim 26, wherein
in (c), the opening is formed in a hole shape or a trench shape.

28. The method of claim 26, further comprising:
(k) forming an opening in a central part of the first conductive adhesive layer between (a) and (c).

29. The method of claim 26, further comprising:
(l) forming a barrier film on the semiconductor substrate before (a),
wherein in (a), the first conductive adhesive layer is formed on the barrier film so as to be in contact with the barrier film.

30. The method of claim 26, wherein
in (a), the first conductive adhesive layer is formed by sputtering.

31. A semiconductor storage device manufacturing method, comprising:
(a) selectively forming a first conductive adhesive layer over a semiconductor substrate;
(b) forming an insulating film on the semiconductor substrate to cover the first conductive adhesive layer;
(c) forming in the insulating film an opening passing through a central part of the first conductive adhesive layer by selectively etching the insulating film and the first conductive adhesive layer;
(d) forming a first conductive film along a bottom surface and a wall surface of the opening;
(e) forming an insulating metal oxide film on the first conductive film;
(f) crystallizing the insulating metal oxide film by performing thermal treatment on the insulating metal oxide film;
(g) forming a second conductive film on the insulating metal oxide film; and
(h) performing patterning so as to leave the second conductive film, the insulating metal oxide film, and the first conductive film in the opening to form a top electrode from the second conductive layer, to form a capacitive insulating film from the insulating metal oxide film, and to form a bottom electrode from the first conductive film, thereby forming a capacitive element including the bottom electrode, the capacitive insulating film, and the top electrode,
wherein in (c), the opening is formed so that the first conductive film in (d) is in contact with the first conductive adhesive layer only at a wall surface part of the opening which includes a corner where the bottom surface of the opening meets the wall surface thereof.

32. The method of claim 31, wherein
in (c), the opening is formed in a hole shape or a trench shape.

33. The method of claim 31, further comprising:
(l) forming a barrier film on the semiconductor substrate before (a),
wherein in (a), the first conductive adhesive layer is formed on the barrier film so as to be in contact with the barrier film.

34. The method of claim 31, wherein
in (a), the first conductive adhesive layer is formed by sputtering.

35. A semiconductor storage device manufacturing method, comprising:
(a) selectively forming a first conductive adhesive layer over a semiconductor substrate;
(b) performing first thermal treatment on the first conductive adhesive layer;
(c) forming, after (b), a second conductive adhesive layer on the first conductive adhesive layer;
(d) forming an insulating film on the semiconductor substrate to cover the first conductive adhesive layer and the second conductive adhesive layer;
(e) forming in the insulating film an opening passing through a central part of the second conductive adhesive layer and exposing a central part of the first conductive adhesive layer by selectively etching the insulating film and the second conductive adhesive layer;
(f) forming a first conductive film along a bottom surface and a wall surface of the opening;
(g) forming an insulating metal oxide film on the first conductive film;
(h) performing second thermal treatment on the insulating metal oxide film to crystallize the insulating metal oxide film;
(i) forming a second conductive film on the insulating metal oxide film; and
(j) performing patterning so as to leave the second conductive film, the insulating metal oxide film, and the first conductive film in the opening to form a top electrode from the second conductive layer, to form a capacitive insulating film from the insulating metal oxide film, and to form a bottom electrode from the first conductive film, thereby forming a capacitive element including the bottom electrode, the capacitive insulating film, and the top electrode,
wherein in (e), the opening is formed so that the first conductive film in (f) is in contact with the first conductive adhesive layer only at a bottom surface part of the opening which includes a corner where the bottom surface of the opening meets the wall surface thereof, while being in contact with the second conductive adhesive layer only at a wall surface part of the opening which includes the corner where the bottom surface of the opening meets the wall surface thereof.

36. The method of claim 35, wherein
in (e), the opening is formed in a hole shape or a trench shape.

37. The method of claim 35, further comprising:
(k) forming an opening in a central part of the first conductive adhesive layer between (a) and (c).

38. The method of claim 35, further comprising:
(l) forming a barrier film on the semiconductor substrate before (a),
wherein in (a), the first conductive adhesive layer is formed on the barrier film so as to be in contact with the barrier film.

39. The method of claim 35, wherein
in (a), the first conductive adhesive layer is formed by sputtering.

40. The method of claim 35, wherein
in (c), the second conductive adhesive layer is formed by sputtering.
